(19) United States
(12) Patent Application Publication
(10) Pub. No.: US 2009/0160070 A1
(43) Pub. Date: Jun. 25, 2009

(54) METAL LINE IN A SEMICONDUCTOR DEVICE

(75) Inventor: Ki-jun Yun, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/268,264

(22) Filed: Nov. 10, 2008

(30) Foreign Application Priority Data
Dec. 24, 2007 (KR) 10-2007-0136741

(51) Int. Cl. H01L 23/522; H01L 21/44

(52) U.S. Cl. 257/784; 438/669; 257/E23.142

(57) ABSTRACT

A semiconductor having a metal line and a method of manufacturing a metal line in a semiconductor device is disclosed. In one example embodiment, a method of manufacturing a metal line in a semiconductor device includes various acts. A metal film for a metal line is formed on an interlayer dielectric layer of a semiconductor substrate. A silicon oxide hard mask film is formed on the metal film. A bottom anti-reflection (BARC) layer is formed on the hard mask film. The BARC layer, the hard mask film, and the metal film are selectively dry etched to form a metal line.

### CROSS-REFERENCE TO A RELATED APPLICATION

This application claims the benefit of Korean Patent Application No. 10-2007-0136741, filed on Dec. 24, 2007 which is hereby incorporated by reference as if fully set forth herein.

### BACKGROUND

1. Field of the Invention

Embodiments of the present invention relate to methods of manufacturing a semiconductor device, and in particular, to a method of manufacturing a metal line in a semiconductor device.

2. Description of the Related Art

A photography process is a photolithography technology used to form a pattern on a semiconductor substrate wafer using light beams. For example, photoresist may be coated at a position on a semiconductor substrate wafer where a pattern, such as a dielectric film or a conductive film, is to be formed. The solubility of photoresist changes depending on light from exposure instruments, such as electron beams or x-rays. Next, the photoresist is partially exposed to the light beams using a photomask. Then, a developing solution is applied to the photoresist. Next, a high soluble portion of the photoresist is removed. Thus, a photoresist pattern is formed. Next, an exposed portion is removed by etching using the photoresist pattern as an etching mask, such that a desired pattern of a semiconductor device is formed on the wafer.

As semiconductor devices become more and more highly integrated, the size of the semiconductor devices is reduced and pitch of the metal line of the semiconductor devices is reduced. In order to implement a fine metal pattern in a highly integrated semiconductor device, a light source in an exposure process is substituted with a light source which emits a light beam with a shorter wavelength. For example, in order to implement a fine pattern of 1 mm and 90 nm or less, an exposure instrument is employed which uses a krypton fluoride (KrF) excimer laser with a wavelength of 248 nm or an argon fluoride (ArF) excimer laser with a wavelength of 93 nm.

In addition, in order to increase the resolution of the metal pattern during the exposure process, a bottom anti-reflection (BARC) layer may be further provided below the photoresist pattern. The BARC layer ensures reduction in height of the photoresist pattern, and prevents a reflection effect during the exposure process. The anti-reflection layer (ARC) has an aromatic polysulfone structure and is mainly made of an organic or inorganic material. Therefore, the ARC layer suppresses an influence of back diffracted light due to sine waves and reflective notching during the exposure process, and as a result, a stable photoresist pattern can be obtained.

FIGS. 1A and 1B are process views sequentially showing a prior art process of patterning a metal line with a BARC layer. As shown in FIG. 1A, a metal film 12 for a metal line is formed on a semiconductor substrate 10. The metal film 12 is a laminate formed sequentially of a first barrier metal film 12a, an aluminum film 12b, and a second barrier metal film 12c. The first barrier metal film 12a and the second barrier metal film 12c may be formed by laminating titanium (Ti) and titanium nitride (TiN) to have thicknesses of 50 Å and 490 Å, respectively. The aluminum film 12b may be formed to have a thickness of 1500 Å.

Next, a BARC layer 14 is formed by laminating silicon nitride (SiN) on the metal film 12 for a metal line by a deposition process to have a thickness of 800 Å. Next, photoresist is coated on the BARC layer 14, by spin coating for example, and exposure and development are performed with a metal line mask, thus forming a photoresist pattern 16. Next, the BARC layer 14 and the metal film 12 are selectively removed by dry etching using a plasma instrument and using the photoresist pattern 16 as an etching mask. Thus, a metal line is manufactured, as shown in FIG. 1B. Thereafter, the photoresist pattern remaining on the BARC layer 14 is removed by ashing.

In this prior art method of manufacturing a metal line, since the BARC layer is provided below the photoresist pattern, during the exposure process, an anti-reflection effect can be obtained. In addition, the photoresist pattern can be reduced in thickness by the thickness of the BARC layer. In order to implement a metal line with a fine line width, the thickness of the photoresist is inevitably limited due to a restriction in focus of the photography process. Accordingly, when the photoresist pattern has a relatively large thickness, during the etching process for forming a metal line the photoresist pattern serves as an etching mask, and thus patterning can be performed while the upper surface of the metal film for a metal line or the BARC layer is protected.

However, as shown in FIG. 2, when the photoresist pattern is reduced in thickness so as to focus on shorter wavelengths of the light source for exposure, the photoresist pattern cannot serve as an etching mask for the underlying metal film for a metal line. Therefore, the photoresist pattern is etched, and the upper edge of the BARC layer or the metal film for a metal line is overetched, as indicated by reference numeral 18. This problem makes it difficult or impossible to pattern a metal line at a desired thickness, and thus the edge of the metal line is overetched. As a result, electrical characteristics of the metal line and yield are deteriorated.

### SUMMARY OF EXAMPLE EMBODIMENTS

In general, example embodiments of the present invention relate to methods of manufacturing a metal line in a semiconductor device which are capable of preventing an upper edge of a metal line from being overetched during a patterning process for a metal line with a fine line width. Some example methods disclosed herein provide a hard mask made of silicon oxide between a metal film for a metal line and a bottom anti-reflection (BARC) layer.

In one example embodiment, a method of manufacturing a metal line in a semiconductor device includes various acts. First, a metal film for a metal line is formed on an interlayer dielectric layer of a semiconductor substrate. Next, a silicon oxide hard mask film is formed on the metal film. Then, a BARC layer is formed on the hard mask film. Next, the BARC layer, the hard mask film, and the metal film are selectively dry etched to form a metal line.

In another example embodiment, a metal line in a semiconductor device includes a metal film, a silicon oxide hard mask film, and a BARC layer. The metal film is formed on an interlayer dielectric layer of a semiconductor substrate. The silicon oxide hard mask film is formed on the metal film. The BARC layer is formed on the hard mask film.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Aspects of example embodiments of the present invention will become apparent from the following detailed description of example embodiments given in conjunction with the accompanying drawings, in which:

FIGS. 1A and 1B are process views sequentially showing a prior art process of patterning a metal line with a bottom anti-reflection (BARC) layer;

FIG. 2 is a sectional view showing an overetched upper edge of a BARC layer or an overetched metal film for a metal line; and

FIGS. 3A to 3C are process views sequentially showing an example process of manufacturing a metal line in a semiconductor device.

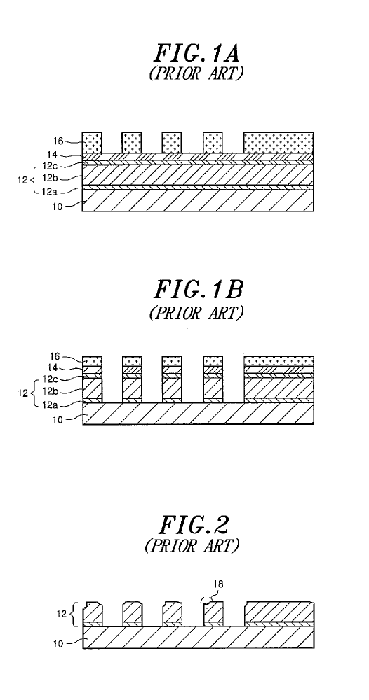

### DETAILED DESCRIPTION OF EXAMPLE EMBODIMENTS

In general, example embodiments of the present invention relate to methods of manufacturing a metal line in a semiconductor device. In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

In some example embodiments of the present invention, a first barrier metal film, an aluminum film, and a second barrier metal film are laminated on an interlayer dielectric layer of a semiconductor substrate, thereby forming a metal film for a metal line. Next, a hard mask film made of silicon oxide (SiO₂) is formed on the metal film, and a bottom anti-reflection (BARC) layer is formed on the hard mask film. Next, the BARC layer, the hard mask film, and the metal film are selectively removed by dry etching to form a metal line. With this configuration, during a patterning process for a metal line with a fine line width, even if the thickness of a photoresist pattern is reduced, a hard mask film can prevent the upper edge of the metal line from being overetched.

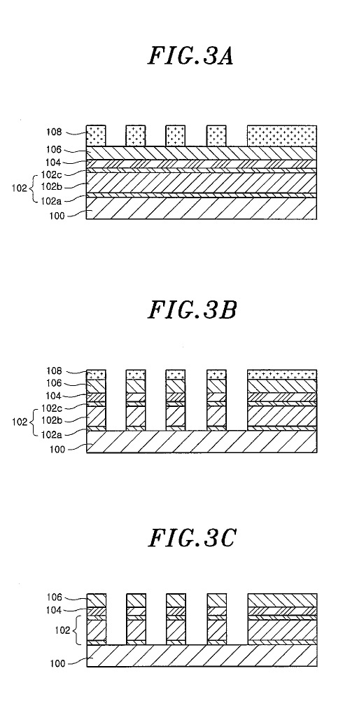

FIGS. 3A to 3C are process views sequentially showing an example process of manufacturing a metal line in a semiconductor device. Though not shown in the drawings, a process of manufacturing a semiconductor device may be performed on a semiconductor substrate. For example, a device isolation film for defining an active region and a passive region is formed on the silicon semiconductor substrate, for example, by an shallow trench isolation (STI) process or the like, and an n-type or p-type dopant may be ion-implanted into the semiconductor substrate, on which the device isolation film, to thereby form a well (not shown).

Next, a gate electrode may be formed on the semiconductor substrate with a gate insulating film (not shown) interposed therebetween, and an n-type or p-type dopant may be ion-implanted to form source/drain regions in the semiconductor substrate around the edges of the gate electrode. Before the source/drain regions are formed, spacers made of an insulating material may be further formed on the side walls of the gate electrode.

Next, one of Undoped Silicate Glass (USG), Boro Silicate Glass (BSG), Boro Phospho Silicate Glass (BPSG), or Phospho Silicate Glass (PSG) may be laminated on the entire surface of the structure in which the source/drain regions are formed, to thereby form an interlayer dielectric layer, such as a Pre Metal Dielectric (PMD) layer. The interlayer dielectric layer is planarized by chemical mechanical polishing (CMP).

Thereafter, contact holes through which the source/drain regions and the gate electrode are exposed are formed in the interlayer dielectric layer by dry etching. Next, a metal, such as tungsten (W) or the like, is filled into the contact holes by PVD (Physical Vapor Deposition), and then patterned by photography and dry etching, to thereby form contact electrodes.

Next, as disclosed in FIG. 3A, an inter-metal dielectric (IMD) layer 100 may be formed on the entire surface of the semiconductor substrate in which the contact electrodes are formed. The IMD layer 100 may be polished by CMP to a predetermined thickness, such that the surface of the IMD layer 100 is planarized. The IMD layer 100 may be formed by laminating TEOS or silicon nitride (SiH₄) by Plasma Enhanced (PE) Chemical Vapor Deposition (CVD) or may be formed by laminating silicon oxide (SiO₂) by High Density Plasma (HDP) CVD.

Next, a metal film 102 for a metal line is formed on the planarized IMD layer 100 by PVD. The metal film 102 may be made of aluminum (Al), copper (Cu), cobalt (Co), tungsten (W), titanium (Ti), nickel (Ni), tantalum (Ta), titanium nitride (TiN), tantalum nitride (TaN), and tungsten nitride (WN), or some combination thereof The metal film 102 may be formed, for example, by sequentially laminating a first barrier metal film 102a, an aluminum film 102b, and a second barrier metal film 102c. The first barrier metal film 102a and the second barrier metal film 102c may be formed by laminating titanium (Ti) and titanium nitride (TiN) to have thicknesses of about 50 Å and about 490 Å, respectively. The aluminum film 102b may be formed to have a thickness of about 1500 Å.

Next, a hard mask film 104 made of silicon oxide (SiO₂) is formed on the metal film 102 for a metal line by CVD. The hard mask film 104 may be formed to have a thickness between about 300 Å and about 700 Å. During a subsequent dry etching process, the hard mask film 104 serves as an etching mask for the metal film 102, together with a photoresist pattern having a reduced thickness, thereby preventing the edge of the metal film 102 from being overetched.

Next, silicon nitride (SiN) may be deposited on the hard mask film 104 by CVD, to thereby form a BARC layer 106. The hard mask film 104 has etching selectivity with respect to the BARC layer 106. The BARC layer 106 may be formed to have a thickness of about 800 Å, for example.

Next, photoresist may be coated on the BARC layer 106 by spin coating and patterned by exposure and development with a metal line mask. Thus, a photoresist pattern 108 for defining a metal line with a fine line width is formed.

Next, the BARC layer 106, the hard mask film 104, the metal film 102 for a metal line are selectively patterned (removed) by dry etching using a plasma instrument with the photoresist pattern 108 as an etching mask. Thus, as shown in FIG. 3B, a metal line with a fine line width is formed. The dry etching process may use carbon-fluoride-based (CF-based) gas and oxygen (O₂) or argon (Ar) gas. The plasma etching process may be performed by using an etching instrument, such as Magnetically Enhanced Reactive Ion Etching (MERIE), Single Frequency-Capacitively Coupled Plasmas (SF-CCP), Double Frequency-Capacitively Coupled Plasmas (DF-CCP), Ultra High Frequency-Capacitively Coupled Plasmas (UHF-CCP), Inductively Coupled Plasmas (ICP), or Electron Cyclotron Resonance (ECR) plasmas.

Specifically, the BARC layer 106 and the hard mask film 104 may be etched by using an Reactive Ion Etching (RIE) type plasma etching instrument with a chamber pressure of about 80 mTorr, power between about 700 W and about 750 W, CF₄ gas of about 80 sccm, Ar gas of about 300 sccm, O₂ gas of about 8 sccm, and He gas of between about 10 sccm and about 30 sccm. The metal film 102 may be etched with a chamber pressure of about 8 mTorr, power between about 10 W and about 800 W, Cl₂ gas of about 55 sccm, BCl₃ gas of about 50 sccm, Ar gas of about 40 sccm, and CHF₃ gas of about 5 sccm.

Next, the photoresist pattern remaining on the BARC layer 106 is removed, by ashing or a similar process for example. Thus, as disclosed in FIG. 3C, a metal line is completed. Next, though not disclosed in the drawings, a dielectric material, such as silicon oxide (SiO₂), is deposited on the entire surface of the IMD layer 100, on which the metal line is formed, by HDP CVD, to thereby form an interlayer dielectric layer. And, the surface of the interlayer dielectric layer is planarized by CMP. Thereafter, the example process of manufacturing a metal line just described may be performed on the planarized interlayer dielectric layer. In this way, a multilayer metal line can be manufactured.

As disclosed herein, the first barrier metal film, the aluminum film, and the second barrier metal film are sequentially laminated on the interlayer dielectric layer of the semiconductor substrate to thereby form the metal film for a metal line. Next, the hard mask film made of silicon oxide (SiO₂) is formed on the metal film to have a thickness between about 300 Å and about 700 Å, and the BARC layer is formed on the hard mask film. Next, the BARC layer, the hard mask film, and the metal film for a metal line are selectively etched by dry etching, to thereby form the metal line.

Although example embodiments of the present invention have been shown and described, various modifications and variations might be made to these example embodiments. The scope of the invention is therefore defined in the following claims and their equivalents.

What is claimed is:

1. A method of manufacturing a metal line in a semiconductor device, the method comprising:
forming a metal film on an interlayer dielectric layer of a semiconductor substrate;
forming a hard mask film on the metal film, the hard mask film comprising silicon oxide;
forming a bottom anti-reflection (BARC) layer on the hard mask film; and
selectively dry etching the BARC layer, the hard mask film, and the metal film to form a metal line.

2. The method of claim 1, wherein the hard mask film is formed by chemical vapor deposition (CVD).

3. The method of claim 1, wherein the hard mask film has a thickness between about 300 Å and about 700 Å.

4. The method of claim 1, wherein the hard mask film serves as an etching mask during the dry etching.

5. The method of claim 1, wherein the dry etching uses carbon-fluoride-based gas and oxygen or argon gas.

6. The method of claim 1, wherein the hard mask film has etching selectivity with respect to the BARC layer made of an insulating film.

7. The method of claim 1, wherein a silicon nitride (SiN) is deposited to thereby form the BARC layer.

8. The method of claim 1, wherein the BARC layer is formed to have a thickness of about 800 Å.

9. A metal line in a semiconductor device comprising:
a metal film formed on an interlayer dielectric layer of a semiconductor substrate;
a hard mask film formed on the metal film; and
a bottom anti-reflection (BARC) layer formed on the hard mask film.

10. The metal line of claim 9, wherein the hard mask film is formed by CVD.

11. The metal line of claim 9, wherein the hard mask film has a thickness between about 300 Å and about 700 Å.

12. The metal line of claim 9, wherein the hard mask film serves as an etching mask during a dry etching process in which the metal line is formed.

13. The metal line of claim 9, wherein the dry etching process uses carbon-fluoride-based gas and oxygen or argon gas.

14. The metal line of claim 9, wherein the hard mask film has etching selectivity with respect to the BARC layer made of an insulating film.

15. The metal line of claim 9, wherein a silicon nitride (SiN) is deposited to thereby form the BARC layer.

16. The metal line of claim 9, wherein the BARC layer has a thickness of about 800 Å.

17. The metal line of claim 9, wherein the hard mask film comprises silicon oxide.
